(19) United States
(12) Patent Application Publication
(10) Pub. No.: US 2025/0357266 A1
(43) Pub. Date: Nov. 20, 2025

(54) COOLING SYSTEM WITH INTEGRATED MICRO COOLER

(71) Applicant: Taiwan Semiconductor Manufacturing Company, Ltd., Hsin-Chu (TW)

(72) Inventors: Li Wang, Hsinchu City (TW); Chien-Yuan Huang, Hsinchu (TW); Shih-Chang Ku, Taipei City (TW); Cheng-Chieh Hsieh, Tainan (TW); Yu-Jen Lien, Tainan City (TW)

(21) Appl. No.: 18/668,646

(22) Filed: May 20, 2024

(51) Int. Cl. H01L 23/473; H01L 23/40

(52) U.S. Cl. CPC H01L 23/473; H01L 23/4006

(57) ABSTRACT

A method of making a cooling unit includes providing a workpiece. The workpiece includes a device substrate and a passivation structure disposed over the device substrate. The method further includes bonding a first carrier piece to the passivation structure, bonding an integrated micro cooler (IMC) precursor to the device substrate by a bonding layer, removing the first carrier piece, bonding a second carrier to the passivation structure, etching the IMC precursor to form a plurality of trenches and a partition wall surrounding the plurality of trenches, thereby forming an IMC, and bonding a cooling cover to the IMC. The IMC precursor includes single crystal diamond (SCD). The cooling cover includes a fluid inlet port and a fluid outlet port connected to the plurality of trenches by fluid conduits.

### BACKGROUND

The semiconductor integrated circuit (IC) industry has experienced exponential growth. Technological advances in IC materials and design have produced generations of ICs where each generation has smaller and more complex circuits than the previous generation. This scaling down process generally provides benefits by increasing production efficiency and lowering associated costs. Such scaling down has also impacted the efficiency and complexity of heat dissipation of ICs. Therefore, while existing IC heat dissipation systems, and the method making the same are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a schematic view of a cooling system having a cooling unit constructed in accordance with some embodiments of the present disclosure.

FIG. 2A illustrates an exploded isometric view of the cooling unit in accordance with some embodiments of the present disclosure.

FIG. 2B illustrates an isometric view of a cooling cover of the cooling unit in accordance with some embodiments of the present disclosure.

FIG. 3 illustrates an isometric view of the cooling unit in accordance with some embodiments of the present disclosure.

FIG. 4 illustrates a top view of a portion of the cooling unit 200 in accordance with some embodiments of the present disclosure.

FIG. 5 illustrates a schematic cross-sectional view of a portion of the cooling unit along an A-A′ line as in FIG. 4 in accordance with some embodiments of the present disclosure.

FIGS. 6A, 6B, 6C, 6D, 6E, and 6F illustrate top views of a portion of an integrated micro cooler (IMC) of the cooling unit in accordance with some embodiments of the present disclosure.

FIG. 7 illustrates a flowchart of a method for forming the cooling unit in accordance with some embodiments of the present disclosure.

FIGS. 8, 9, 10, 11, 12, 13, 14, and 15 are fragmentary cross-sectional views of an exemplary workpiece at various fabrication stages associated with the method of FIG. 7 according to various aspects of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

Generally, an IC chip includes active devices formed on a semiconductor substrate and an interconnect structure to functionally interconnect the active devices. An IC chip may also be referred to as an IC die or simply, a die. A typical problem with dies is heat dissipation during operation. A prolonged exposure of a die by operating at excessive temperatures may decrease the reliability and operating lifetime of the die. This problem may become severe if the die is a computing die such as a central processing unit (CPU), which generates a lot of heat. As such, improvements to heat transfer are still needed.

The present disclosure provides various embodiments of a cooling system. Particularly, the present disclosure provides a cooling system having a cooling unit. The cooling unit includes a die, an integrated micro cooler (IMC) integrated with the die, and a cooling cover disposed over the IMC. The IMC may be bonded to the die by a bonding layer including a thermal interface material (TIM). The bonding layer may have a thermal resistance of equal to or less than about 0.05 mm²·C/W. The IMC includes trenches open to inlet conduits and outlet conduits of the cooling cover. The IMC includes greater than about 90 weight percent (wt %) of single crystal diamond (SCD). During operation, a coolant may sequentially flow through the inlet conduits in the cooling cover, the trenches in the IMC, and the outlet conduits in the cooling cover. Heat generated from the die may be transferred to the coolant in the trenches. By having the IMC, the bonding layer, and the cooling cover in the present disclosure, efficiency of heat transfer from the die to the coolant may be increased. Heat accumulation in the die may be reduced and thermal damage to the die may be prevented. The cooling system may further include a heat exchanger to cool the coolant flowing out of the cooling unit and a pump to drive the coolant flow. Power consumption of the pump may be reduced by using the cooling unit in this disclosure.

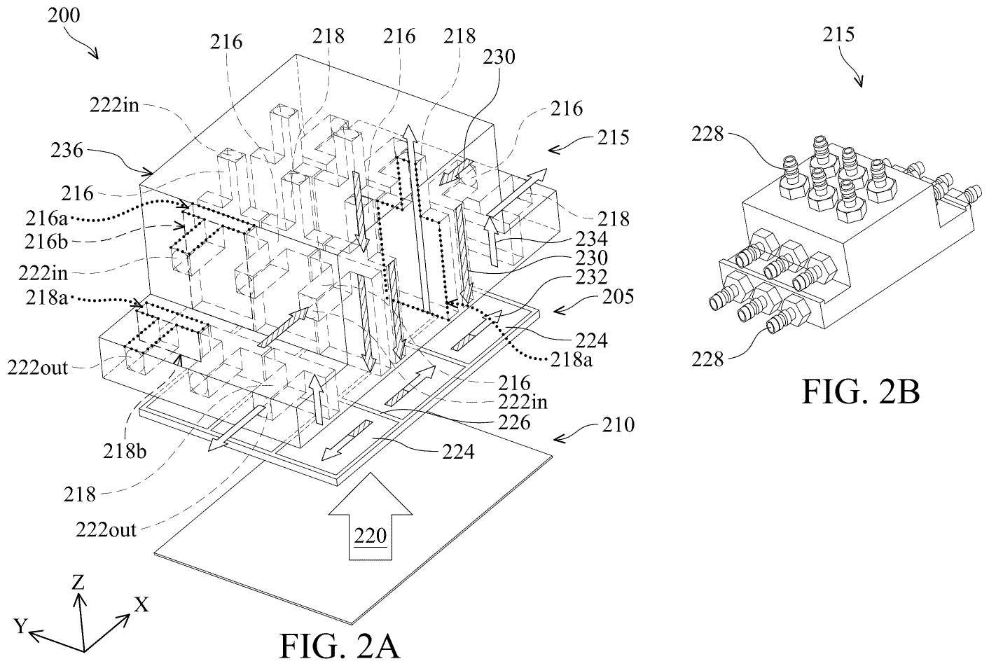

The various aspects of the present disclosure will now be described in more detail with reference to the figures. For avoidance, the X, Y and Z directions in FIGS. 2-6F and 8-15 are perpendicular to one another. Additionally, throughout the disclosure, like reference numerals may denote like features.

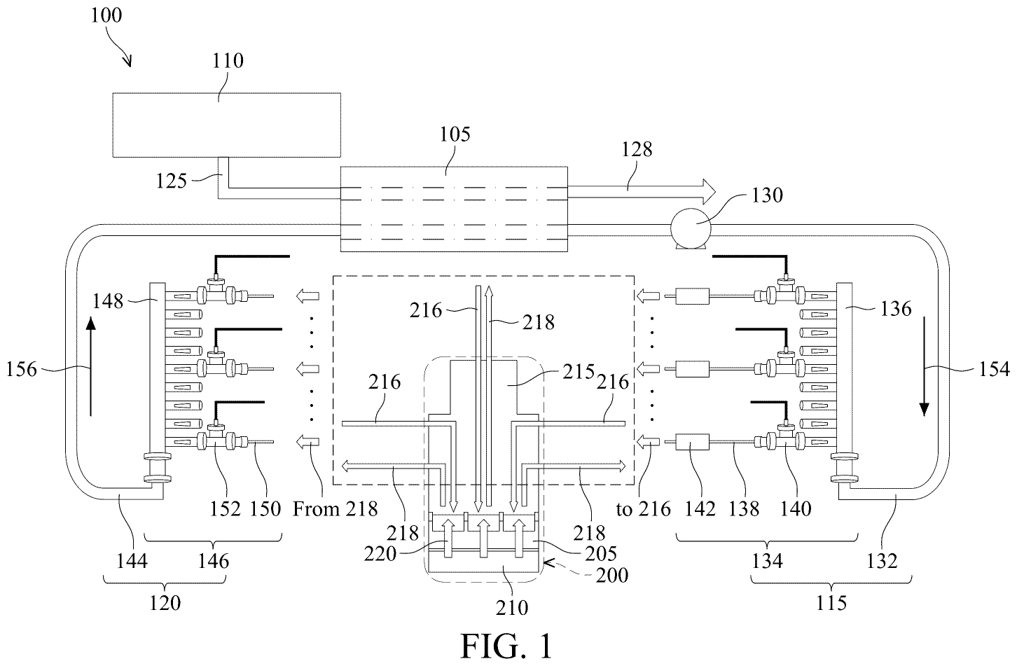

FIG. 1 illustrates a schematic view of a cooling system 100 constructed in accordance with some embodiments of the present disclosure. In some embodiments, the cooling system 100 includes a cooling unit 200, a heat exchanger 105, a cooling water supply 110, a first conduit 115 and a second conduit 120 connecting the heat exchanger 105 and the cooling unit 200, a first cooling water conduit 125 connecting the cooling water supply 110 and the heat exchanger 105, and a second cooling water conduit 128 connected to the heat exchanger 105. In this disclosure, a conduit is one or more channel(s) and provides a path for conveying water or other fluid, such as a coolant. A conduit may include pipe(s), tube(s), valve(s), any other suitable equipment, or any combination thereof. The cooling system 100 may include any suitable numbers of the cooling units 200, such as including one, two, three, four, five, etc. of the cooling units 200. In some embodiments, the cooling system 100 further includes a pump 130 on the first conduit 115.

In some embodiments, the cooling unit 200 includes a die 210, an IMC 205 disposed above and bonded to the die 210, and a cooling cover 215 disposed above and bonded to the IMC 205.

The cooling cover 215 may include inlet conduits 216 and outlet conduits 218 connected to the first conduit 115 and the second conduit 120, respectively. The inlet conduits 216 and the outlet conduits 218 are illustrated with arrows to show direction of coolant flows in the inlet conduits 216 and the outlet conduits 218. It is noted that positions and numbers of the inlet conduits 216 and the outlet conduits 218 are for illustration purpose only. Details will be described later in the disclosure.

In some embodiments, the first conduit 115 includes a first pipe 132 and an inlet connection skid 134 connected to the first pipe 132. The first pipe 132 is connected to the heat exchanger 105. The inlet connection skid 134 connected to the cooling unit 200. In some embodiments, the pump 130 is on the first pipe 132. The inlet connection skid 134 may include a branching unit 136, which is connected to the first pipe 132 and branch conduits 138. The branching unit 136 may include a main pipe connected to the first pipe 132 and a plurality of side openings. Each of the plurality of side openings is connected to one of the branch conduits 138. The one of the branch conduits 138 may be connected to one of the inlet conduits 216. In some embodiments, the inlet connection skid 134 further includes a pressure gauge 140 on each of the branch conduits 138. The pressure gauge 140 may be used to measure pressure of fluid inside the branch conduit 138. The inlet connection skid 134 may further include a flow meter 142 on each of the branch conduits 138. The flow meter 142 may measure flow rate of fluid inside the branch conduit 138.

The second conduit 120 may have similar structures as the first conduit 115. In some embodiments, the second conduit 120 includes a second pipe 144 and an outlet connection skid 146 connected to the second pipe 144. The second pipe 144 is connected to the heat exchanger 105. The outlet connection skid 146 is connected to the cooling unit 200. The outlet connection skid 146 may include a branching unit 148, which is connected to the second pipe 144 and branch conduits 150. The branching unit 148 may include a main pipe connected to the second pipe 144 and a plurality of side openings. Each of the plurality of side openings is connected to one of the branch conduits 150. The one of the branch conduits 150 may be connected to one of the outlet conduits 218. In some embodiments, the outlet connection skid 146 further includes a pressure gauge 152 on each of the branch conduits 150. The pressure gauge 152 may be used to measure pressure of fluid inside the branch conduit 150.

The heat exchanger 105 may include any type of heat exchanger, for example, a shell and tube heat exchanger, a plate type heat exchanger. In some embodiments, the cooling water supply 110 provides cooling water to the heat exchanger 105. The used cooling water then enters the second cooling water conduit 128 and may be cooled by any suitable method. In some embodiments, the used cooling water is cooled and recycled to the cooling water supply 110.

FIG. 1 has been simplified for the sake of clarity to better understand the concepts of the present disclosure. Additional features can be added in the cooling system 100, and some of the features described above can be replaced, modified, or eliminated in other embodiments of the cooling system 100. For example, some features (e.g., valves, pumps, temperature sensors, controllers, filters) are omitted in FIG. 1.

A method of using the cooling system 100 may include circulating a coolant in the first conduit 115, the cooling unit 200, the second conduit 120, and the heat exchanger 105. The coolant may include any suitable coolant, such as water, propylene glycol, 25% propylene glycol (PG25), or a combination thereof. In some embodiments, the coolant is a water-based coolant. In some embodiments, additives are added to water to produce the coolant. Examples of additives include surfactants, corrosion inhibitors, biocides, antifreeze, and the like. The coolant may stay in liquid phase during operation of the system 100.

In some embodiments, the coolant inside the first conduit 115 has a first temperature and flows from the heat exchanger 105 to the cooling unit 200. The arrow 154 illustrates the direction of the coolant flow. The coolant flow in the first pipe 132 is divided into the branch conduits 138 by the branching unit 136. Temperature, pressure, flow rate, etc. of the coolant in the branch conduits 138 may be monitored and/or controlled.

The coolant from the branch conduits 138 then enters the inlet conduits 216 and flows into trenches of the IMC 205. In the trenches of the IMC 205, the coolant exchanges heat with the die 210. For example, heat 220 generated in the die 210 during operation is transferred from the die 210 to the coolant in the trenches of the IMC 205. After the heat exchanging, the coolant flows from trenches of the IMC 205 through the outlet conduits 218 to the branch conduits 150. The coolant inside the second conduit 120 may have a second temperature greater than the first temperature. The coolant flows from the branch conduits 150, merges at the branching unit 148, and then flows to the heat exchanger 105 via the second pipe 144. The arrow 156 illustrates the direction of the coolant flow. Temperature, pressure, flow rate, etc. of the coolant in the branch conduits 150 may be monitored and/or controlled.

The coolant from the second conduit 120 then flows through the heat exchanger 105 and into the first conduit 115. In the heat exchanger 105, the coolant is cooled (e.g., from the second temperature to the first temperature) by the cooling water from the cooling water supply 110.

FIG. 2A illustrates an exploded isometric view of the cooling unit 200 and FIG. 2B illustrates an isometric view of the cooling cover 215 in accordance with some embodiments of the present disclosure.

In FIG. 2A, the cooling unit 200, the IMC 205, and the die 210 are vertically separated for a purpose of clarity. Components of the cooling cover 215 are shown even though the cooling cover 215 may not necessarily be transparent. The cooling cover 215 may have an up-side-down T shape in a cross-sectional view in an X-Z plane. The inlet conduits 216 may each include a T-shaped portion 216a (such as in the dashed T shape 216a) open to a fluid inlet port 222in. The T shape may be viewed from a top view. In such embodiments, the inlet conduit 216 may further include a rectangular portion 216b (such as in the dashed rectangular 216b). The rectangular portion 216b may be connected to the top bar of the T-shaped portion 216a. The rectangular portion 216b may vertically extend to and be open to the IMC 205 therebelow. In some other embodiments, the T shape may be viewed from a cross-sectional view in a Y-Z plane. In such embodiments, the inlet conduit 216 may not include a rectangular portion, instead, the top bar of the T-shaped portion 216a may vertically extend to and be open to the IMC 205 therebelow. The outlet conduits 218 have similar structures as the inlet conduits 216. For example, the outlet conduits 218 may each include a T-shaped portion 218a (such as in the dashed T shape 218a) similar to the T-shaped portion 216a and open to a fluid outlet port 222out. In some embodiments, the outlet conduit 218 further include a rectangular portion 218b (such as in the dashed rectangular 218b) similar to the rectangular portion 216b. The outlet conduits 218 may each open to the IMC 205 therebelow.

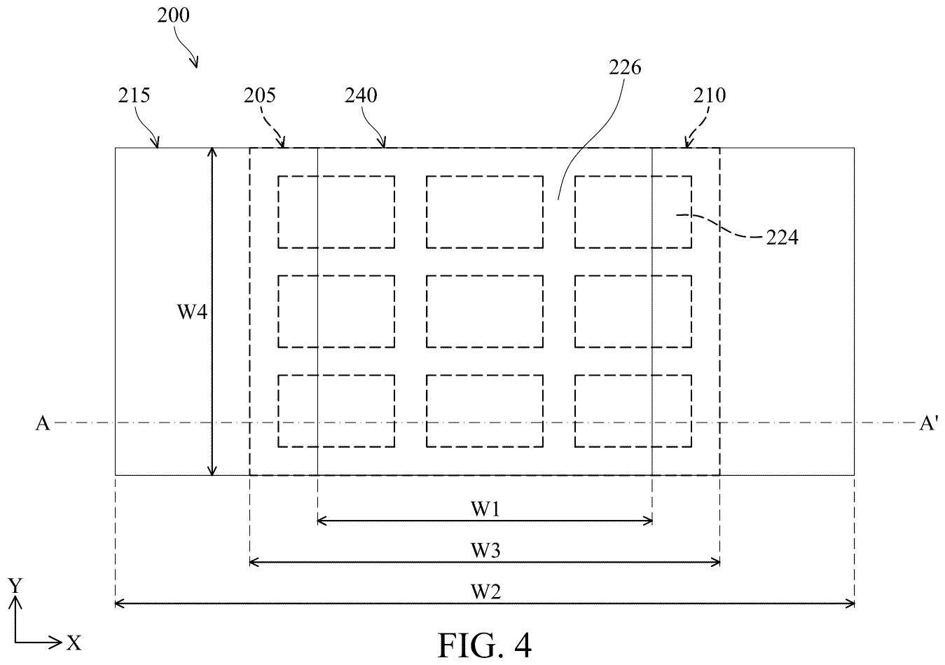

A top portion (also referred to as a top surface portion) of the IMC 205 may be divided into nine regions 224 by partition walls 226 as depicted in FIGS. 2A and 4. One pair of the inlet conduit 216 and the outlet conduit 218 are open to (or connected to) each of the region 224. In embodiments, an arrow 230 in the inlet conduit 216, an arrow 232 in the region 224, and an arrow 234 in the outlet conduit 218 illustrates a flow direction of the coolant from the fluid inlet port 222in to the corresponding fluid outlet port 222out.

The inlet conduits 216 and the outlet conduits 218 may extend out of outer walls 236 of the cooling cover 215 and include features 228 designed to accommodate screws (e.g., for connecting branch conduits 138 or 150 in FIG. 1) as in FIG. 2B.

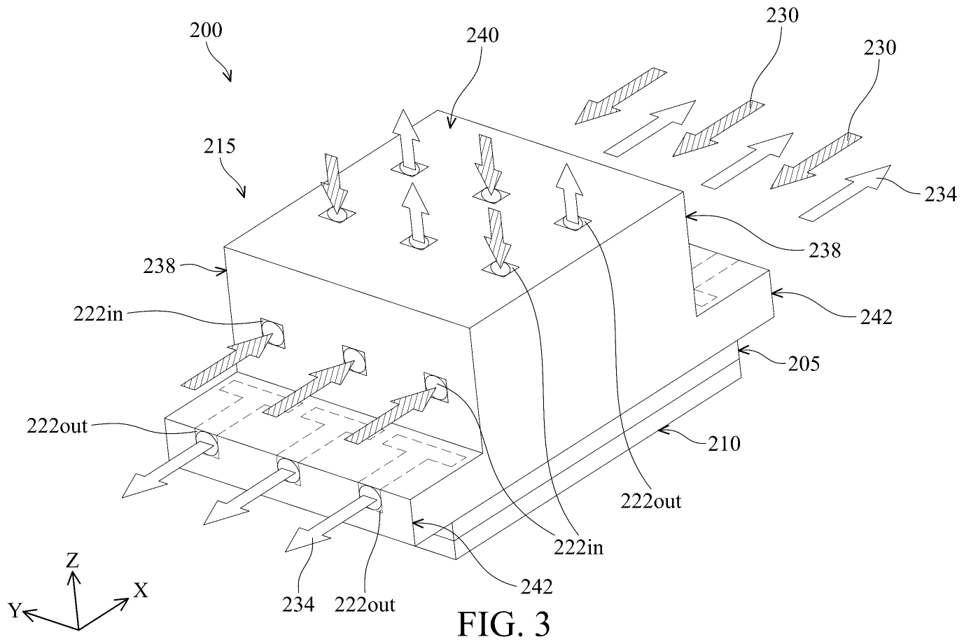

FIG. 3 illustrates an isometric view of the cooling unit 200 in accordance with some embodiments of the present disclosure. In FIG. 3, internal components (e.g., the inlet conduits 216 and the outlet conduits 218) of the cooling cover 215 are not shown. In the depicted example, the fluid inlet ports 222in are on opposing upper sidewalls 238 and a top surface 240 of the cooling cover 215, and the fluid outlet ports 222out are on opposing lower sidewalls 242 and the top surface 240 of the cooling cover 215. The cooling cover 215 includes nine (9) fluid inlet ports 222in and nine (9) fluid outlet ports 222out.

It is noted that in FIGS. 2A and 3, positions of the fluid inlet ports 222in, the fluid outlet ports 222out, the inlet conduits 216, and the outlet conduits 218 are for illustration purpose only and should not be construed as limiting the scope of the present disclosure. For example, an inlet conduit 216 and a corresponding outlet conduit 218 may switch their positions.

FIG. 4 illustrates a top view of the cooling unit 200 in accordance with some embodiments of the present disclosure. In the depicted embodiment, the regions 224 have rectangular shapes in similar dimensions. The top surface 240 of the cooling cover 215 may have a width W1 along the X-direction. The cooling cover 215 may have a total width W2 along the X-direction. The IMC 205 may have a width W3 along the X-direction, greater than W1 and smaller than W2. W3 may be about 20 mm to about 30 mm. The cooling cover 215 and the IMC 205 may have a width W4 along the Y-direction in a range of about 15 mm to about 30 mm. The die 210 may have dimensions similar to the IMC 205 as depicted or have widths greater than W3 and W4 along the X-direction and the Y-direction, respectively.

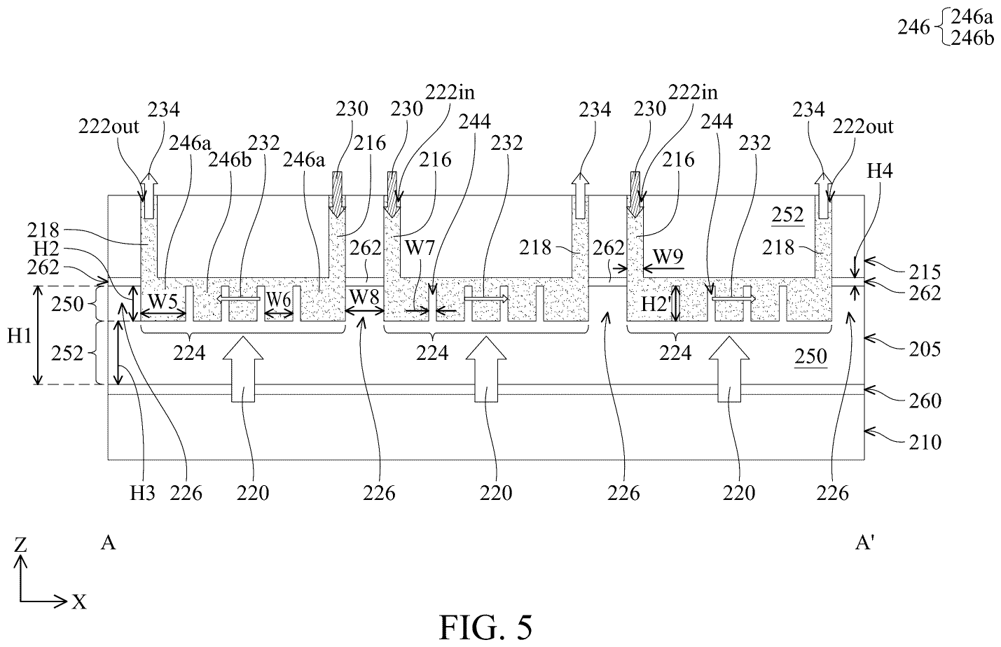

FIG. 5 illustrates a cross-sectional view of the cooling unit 200 along an A-A′ line as in FIG. 4 in accordance with some embodiments of the present disclosure. In FIG. 5, features of the cooling cover 215 (e.g., the up-side-down T-shape, the inlet conduits 216, the outlet conduits 218) have been simplified or omitted for the sake of clarity to better understand the inventive concepts of the present disclosure. Similar as FIGS. 2A and 3, an inlet conduit 216 and a corresponding outlet conduit 218 may switch their positions. The coolant flowing inside the inlet conduits 216 and the outlet conduits 218 of the cooling cover 215 are shown as the arrows 230 and 234, respectively. In the depicted embodiment, the arrows 232 show the direction of the coolant flowing in the IMC 205. The heat 220 is transferred from the die 210 to the coolant flowing in the IMC 205.

The die 210 may be an IC chip, a system on chip (SoC), or portions thereof, that may include various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. The die 210 may be any suitable chips, such as memory chips, central processing unit (CPU) chips, graphic processing unit (GPU) chips, input/output (I/O) chips, or combinations thereof.

In some embodiments, the IMC 205 is disposed over the die 210. The IMC 205 may be bonded to the die 210 by a bonding layer 260. The bonding layer 260 is used to improve electrical and/or thermal conduction by filling in microscopic air pockets created between minutely uneven surfaces, such as the region between surfaces of the IMC 205 and the die 210. In some embodiments, the bonding layer 260 has a thickness of about 0.1 μm to about 10 μm. The bonding layer 260 may include a layer of a first thermal interface material (TIM) or a layer of a second TIM to be described below. In some embodiments, the bonding layer 260 includes a layer of the first TIM and a layer of the second TIM. In some embodiments, the layer of the second TIM is disposed over the first TIM to improve the bonding.

In some embodiments, the bonding layer 260 includes a layer of the first TIM. In such embodiments, the bonding layer 260 may have a thermal resistance of about 0.5 mm²·C/W to about 5 mm²·C/W. In some embodiments, the first TIM includes an oxide compound, such as oxidized silicon. The first TIM may be a viscous, silicone compound similar to the mechanical properties of a grease or a gel. The first TIM may have a thermal conductivity of about 1 W/m·K to about 30 W/m·K, such as about 4 W/m·K, for example.

In some embodiments, the bonding layer 260 includes a layer of the second TIM. In such embodiments, the bonding layer 260 may have a thermal resistance of equal to or less than about 0.05 mm²·C/W. In some embodiments, the bonding layer 260 has a thermal resistance of about 0.01 mm²·C/W. In some embodiments, the second TIM is a metal-based thermal paste containing silver, nickel, or aluminum particles suspended in the silicone grease. In other embodiments non-electrically conductive, ceramic-based pastes, filled with ceramic powders such as beryllium oxide, aluminum nitride, aluminum oxide, or zinc oxide, may be applied. In other embodiments, instead of being a paste with a consistency similar to gels or greases, the second TIM may be a solid material. In this embodiment, the second TIM may be a thin sheet of a thermally conductive, solid material. In a particular embodiment the second TIM that is solid may be a thin sheet of indium, nickel, silver, aluminum, combinations and alloys of these, or the like, or other thermally conductive solid material. The second TIM may have a thermal conductivity of about 50 W/m·K to about 500 W/m·K, such as about 400 W/m·K, for example.

In some embodiments, the IMC 205 includes single crystal diamond (SCD). The IMC 205 may include greater than about 90 wt % of SCD and less than about 10% of other materials (e.g., impurities, dopants). SCD may be one single, continuous crystal of diamond. SCD may be formed by any suitable method, such as chemical vapor deposition (CVD) or high-pressure high-temperature (HPHT) processes. In some embodiments, the IMC 205 is doped with a dopant (such as boron and phosphorus). The IMC 205 may have a thermal conductivity of greater than about 2,000 W/m·K. In some embodiments, the IMC 205 has a thermal conductivity of about 2,000 W/m·K to about 3,000 W/m·K. In some embodiments, the IMC 205 has a thermal conductivity of about 2,100 W/m·K to about 2,300 W/m·K. By having increased thermal conductivity as compared to conventional IMCs, efficiency of heat transfer (e.g., heat transfer from the die 210 to the coolant) in the IMC 205 may be increased. In some embodiments, the IMC 205 has a Young's modulus of greater than about 900 GPa. In some embodiments, the IMC 205 has a Young's modulus of about 900 GPa to about 1100 GPa. In some embodiments, the IMC 205 has a hardness of equal to or greater than 9 on the Mohs scale of mineral hardness. For example, the IMC 205 has a hardness of 10 on the Mohs scale of mineral hardness. The Young's modulus and the hardness of the IMC 205 may be greater as compared to conventional IMCs. By having the mechanical properties described above, mechanical integrity of the IMC 205 is increased. Thus, a thickness H1 of the IMC 205 along the Z-direction may be reduced, which further reduces thermal resistance of the IMC 205. Thicknesses in this disclosure may be referred to as heights and are along the Z-direction.

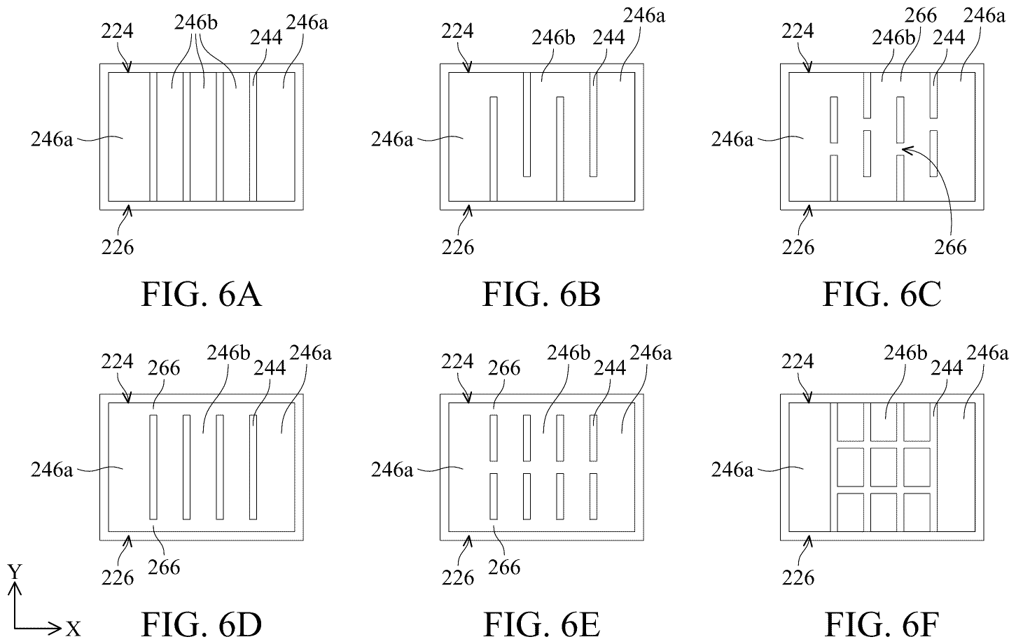

In some embodiments, referring to FIG. 5 and FIGS. 6A-6F, each of the regions 224 in the top portion 250 of the IMC 205 includes walls 244 and trenches 246 divided by the walls 244. The trenches 246 on sides (also referred to as side trenches 246a) may each have a width W5 greater than a width W6 of the trenches 246 (also referred to as central trenches 246b) between the side trenches 246a, W5 and W6 being along the X-direction. The reasons for W5 being greater than W6 include that, the coolant in the side trenches 246a removes additional heat from the adjacent partition wall 226, and the inlet conduit 216 or the outlet conduit 218 is open to the side trenches 246a. The side trenches 246a and the central trenches 246b may be individually or collectively referred to as trench(s) 246 dependent upon the context. In some embodiments, W6 is about 50 μm to about 500 μm. If W6 is too small, heat may accumulate in the portion of the IMC 205 directly below the central trenches 246b. If W6 is too large, the number of the central trenches 246b may be too small, reducing efficiency of the heat transfer to the coolant. A ratio of W5 to W6 (W5/W6) may be about 1.1 to about 1.5. If the ratio W5/W6 is too small, W5 may be too small, and heat may accumulate in the adjacent partition walls 226. If the ratio W5/W6 is too large, W5 may be too large, the number of the central trenches 246b may be too small, reducing efficiency of the heat transfer to the coolant.

The walls 244 may have a width W7 of about 50 μm to about 300 μm. A ratio of W7 to W6 (W7/W6) is about 0.1 to about 1. If the ratio W7/W6 is too small, W7 may be too small and the walls 244 may break during operation. If the ratio W7/W6 is too large, W7 may be too large, thus making available space for the trenches 246 too small. In some embodiments, the partition wall 226 has a width W8 of about 100 μm to about 1,000 μm. W8 may be equal to or greater than W7 and a ratio of W8 to W7 (W8/W7) may be about 1 to about 10. If W8 is too small, mechanical support provided by the partition walls 226 may be too small. If W8 is too large, available space for the trenches 246 may be too small. In some embodiments, the partition walls 226 (or the top portion 250 of the IMC 205) have a height H2 of about 100 μm to about 250 μm. The walls 244 may have a height H2′ of about 100 μm to about 230 μm. H2′ may be equal to or smaller than H2. If H2 or H2′ is too small, the volume of the trenches 246 may be too small, reducing the amount of the coolant in the trenches 246. If H2 or H2′ is too large, the coolant in the bottom of the trenches 246 may stay there for a too long time period, which may reduce efficiency of heat transfer.

In some embodiments, the IMC 205 include a bottom portion 252 below the top portion 250. The bottom portion 252 may have a height H3 of about 180 μm to about 600 μm. In some embodiments, H3 is about 200 μm to about 300 μm. The total height H1 of the IMC 205 may be about 300 μm to about 750 μm. If H1 is too small, the height H3 of the bottom portion 252 of the IMC 205 may be too small, impacting mechanical integrity of the IMC 205 (e.g., increasing possibility of cracking of the IMC 205 during manufacturing or operation of the cooling unit 200); or the height H2 of the partition walls 226 may be too small, reducing available space for the coolant in the IMC 205 and the efficiency of heat removal. If H1 is too large, the thermal resistance of the IMC 205 may be too large, which reduces the benefit of having SCD in the IMC 205.

By including the bonding layer 260 and the IMC 205 described above, heat dissipation from the die 210 is improved. Thus, a flow rate of the coolant in the cooling system 100 may be reduced when removing a same amount of heat from the die 210. Accordingly, power consumption of the pump 130 in the cooling system 100 may be reduced. At the same power consumption, heat removal from the die 210 may increase by greater than about 50%. In addition, any hot spot (e.g., under the partition walls 226) of the die 210 may be reduced and/or eliminated during operation.

In some embodiments, the IMC 205 is bonded to the cooling cover 215 by a sealing layer 262. In some embodiments, the sealing layer 262 is disposed between the partition walls 226 and the cooling cover 215. The partition walls 226 may provide support for the cooling cover 215. The sealing layer 262 may be used for sealing purpose, such as avoiding leaking of the coolant into the environment and/or between adjacent regions 224. Thus, the coolant in a region 224 may be separated from the coolant in an adjacent region 224 by the partition walls 226 and the sealing layer 262. The sealing layer 262 may include a polymer-based material, a silicone-based material, or a combination thereof. In some embodiments, the sealing layer 262 includes silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials.

The sealing layer 262 and the bonding layer 260 may have different compositions. In some embodiments, the sealing layer 262 excludes the second TIM as described above. The sealing layer 262 may have a thermal resistance of equal to or greater than about 1 mm²·C/W, such as about 5 mm²·C/W. In some embodiments, the bonding layer 260 includes a thin sheet of indium, nickel, silver, aluminum, combinations and alloys of these, or the like and has a thermal resistance of equal to or less than about 0.03 mm²·C/W. Thus, a first heat transfer rate in the sealing layer 262 is smaller than a second heat transfer rate in the bonding layer 260. A ratio of the first heat transfer rate to the second heat transfer rate may be about 1:50 to about 1:500. Thus, the heat 220 generated from the die 210 may be mostly transferred to regions 224 and removed by the coolant, which is more efficient than being transferred through the sealing layer 262 and then through environment and/or the cooling cover 215.

In some embodiments, the sealing layer 262 has a thickness H4 of about 20 μm to about 200 μm. If H4 is too small, the bonding and sealing between the cooling cover 215 and the IMC 205 may be too weak. If H4 is too large, the heat dissipation may be impacted.

In some embodiments, the cooling cover 215 includes greater than about 90 wt % of copper (Cu) and less than about 10 wt % of other materials (e.g., impurities, other metals). Cu may provide mechanical integrity to the cooling cover 215. In some embodiments, the cooling cover 215 has a thermal conductivity of about 350 W/m·K to about 450 W/m·K. In some embodiments, the inlet conduits 216 and the outlet conduits 218 each have a width W9 of about 30 μm to about 500 μm. W9 may be smaller than W5. A ratio of W9 to W5 (W9/W5) may be about 0.3 to about 1. If the ratio W9/W5 is too small or W9 is too small, pressure drop in the inlet conduits 216 and the outlet conduits 218 may be too large, which increases the power consumption of the pump 130. If the ratio W9/W5 is too large or W9 is too large, the coolant may flow into the central trenches 246b without flowing into the side trenches 246a, thus time for heat transfer may be too short.

In some alternative embodiments, the cooling cover 215 includes greater than about 50 wt % of SCD and less than about 50 wt % of other materials (e.g., metals such as Cu). For example, the cooling cover 215 includes greater than about 70 wt % SCD. In some embodiment, the cooling cover 215 includes greater than about 90 wt % SCD. In some embodiments, the cooling cover 215 includes SCD, Cu, or a combination thereof. By including SCD, the cooling cover 215 may have an increased mechanical integrity and thermal conductivity. In some embodiments, the cooling cover 215 includes greater than about 70 wt % SCD and the bonding layer 260 includes greater than about 95 wt % of the first TIM. In some embodiments, the cooling cover 215 includes greater than about 70 wt % SCD and the bonding layer 260 includes greater than about 95 wt % of the second TIM.

FIGS. 6A-6F illustrate top views of one of the regions 224 surrounded by a portion of the partition walls 226 in accordance with some embodiments of the present disclosure. The one of the regions 224 may be any of the regions 224 in the IMC 205. In other words, the regions 224 in the IMC 205 may have any combination of the embodiments shown in FIGS. 6A-6F. In FIG. 6A, the walls 244 extend along the Y-direction, both ends of each of the walls 244 contact the partition walls 226, and the trenches 246 are completely separated from each other by the walls 244 from the top view. In FIG. 6B, a difference from FIG. 6A is that, only one end of each of the walls 244 contacts the partition walls 226, and the trenches 246b and 246a merge (or connect) end-to-end to form a zig-zag shaped trench. In FIG. 6C, a difference from FIG. 6B is that, each of the walls 244 are broken into segments (e.g., two segments), such that the adjacent trenches 246 have two merging openings 266 as depicted. In FIG. 6D, a difference from FIG. 6B is that, both ends of each of the walls 244 are spaced apart from the partition walls 226. In FIG. 6E, a difference from FIG. 6D is that, each of the walls 244 is broken into segments (e.g., two segments), such that the adjacent trenches 246 have three merging openings 266 as depicted. In FIG. 6F, a difference from FIG. 6A is that, the walls 244 further includes portions extending along the X-direction, such that each of the trenches 246b in FIG. 6A are further divided into the smaller trenches 246b as in FIG. 6F. In FIGS. 6A-6F, it is understood that the walls 244 and the partition walls 226 may merge as continuous features.

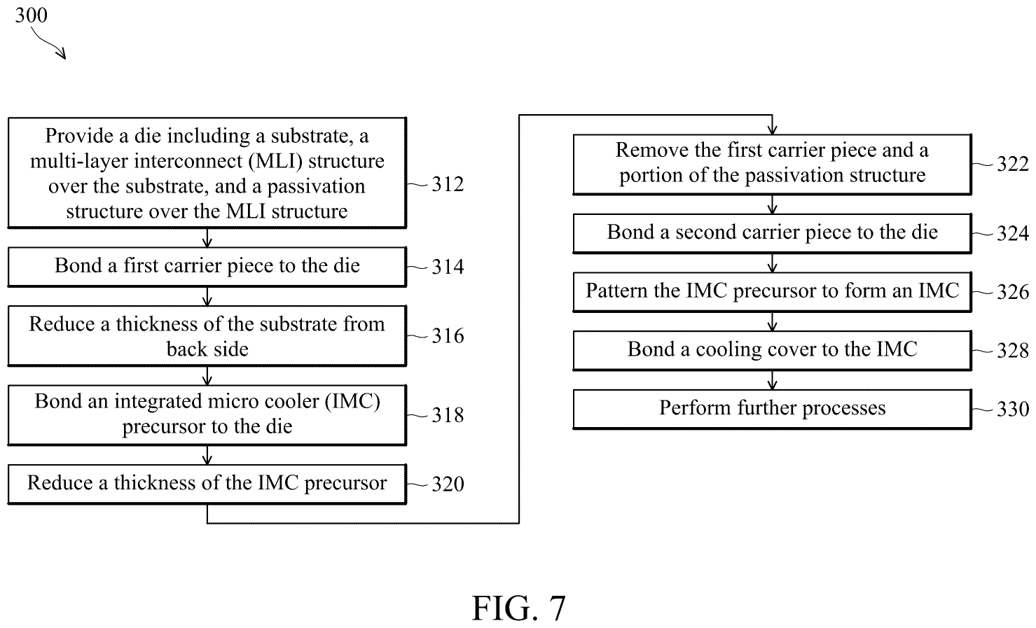

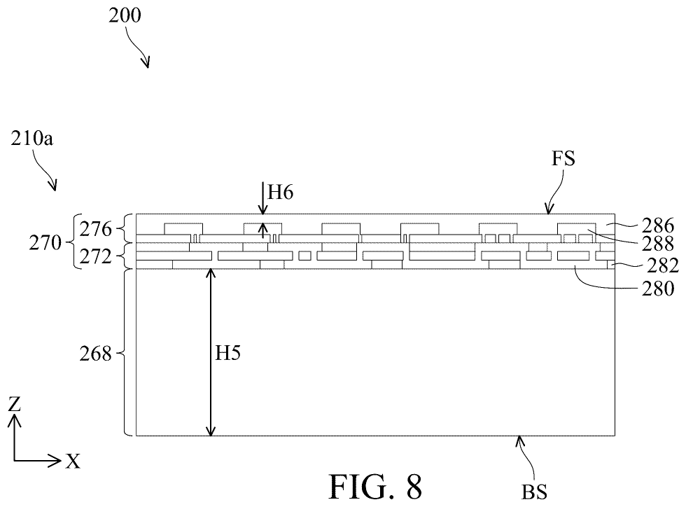

FIG. 7 is a flowchart illustrating a method 300 of forming the cooling unit 200 in accordance with some embodiments of the present disclosure. Method 300 is merely an example and is not intended to limit the present disclosure to what is explicitly illustrated in method 300. Additional steps can be provided before, during, and after the method 30, and some steps described can be replaced, eliminated, or moved around for additional embodiments of the method. Not all steps are described herein in detail for reasons of simplicity. Method 300 is described below in conjunction with FIGS. 8-15, which are fragmentary cross-sectional views of a precursor of the cooling unit 200 at different stages of fabrication along line A-A′ of FIG. 4 in accordance with some embodiments of the present disclosure. Because the precursor will be fabricated into the cooling unit 200 as described above, the precursor may be referred to herein as a precursor 200, a workpiece 200 or a cooling unit 200 as the context requires.

Referring to FIGS. 7 and 8, method 300 includes a block 312 where a die 210a is provided. The die 210a is a precursor of the die 210 as described above. In some embodiments, the die 210a is an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof.

In some embodiments, the die 210a includes a substrate 268 and an interconnection structure 270 over the substrate 268. The die 210a has a front surface FS and a back surface BS opposite to the front surface FS as depicted.

In some embodiments, the substrate 268 may include semiconductor materials, such as semiconductor materials of the groups III-V of the periodic table. In some embodiments, the substrate 268 may include elementary semiconductor materials such as silicon or germanium, compound semiconductor materials such as silicon carbide, gallium arsenic, indium arsenide, or indium phosphide or alloy semiconductor materials such as silicon germanium, silicon germanium carbide, gallium arsenic phosphide, or gallium indium phosphide. For example, the substrate 268 may be a silicon bulk substrate. The die 210a may include active components (e.g., transistors or the like) and, optionally, passive components (e.g., resistors, capacitors, inductors, or the like) formed in the substrate 268. The die 210a may be a logic die, such as a central processing unit (CPU) die, a graphic processing unit (GPU) die, a micro control unit (MCU) die, an input-output (I/O) die, a baseband (BB) die, or an application processor (AP) die. In some alternative embodiments, the die 210a may be a memory die such as a high bandwidth memory die. In some embodiments, the substrate 268 has a height H5 of about 700 μm to about 850 μm.

In some embodiments, the interconnection structure 270 includes a multi-layer interconnect (MLI) structure 272 and a passivation structure 276 over the MLI structure 272.

The MLI structure 272 may include multiple patterned dielectric layers and conductive layers that provide interconnections (e.g., wiring) between the various microelectronic components formed within the substrate 268 and upper conductive features (e.g., conductive pads 288) in the passivation structure 276. As noted, the MLI structure 272 may include a plurality of conductive features 280 connected to the components in the substrate 268 and a plurality of dielectric layers 282 used to provide isolation between the conductive features 280. In some embodiments, the dielectric layers 282 may include silicon oxide or a silicon oxide containing material where silicon exists in various suitable forms. In some examples, the dielectric layers 282 may include a low-k dielectric layer (e.g., having a dielectric constant less than that of SiO₂ which is about 3.9) such as oxide formed from tetraethylorthosilicate (TEOS), undoped silicate glass (USG), or doped silicon oxide such as borophosphosilicate glass (BPSG), fluorosilicate glass (FSG), phosphosilicate glass (PSG), boron doped silicon glass (BSG), and/or other suitable low-k dielectric material.

In some embodiments, the conductive features 280 may include contacts, vias, or metal lines to provide horizontal and vertical interconnections. In some cases, the conductive features 280 include copper (Cu), aluminum (Al), an aluminum copper (AlCu) alloy, ruthenium (Ru), cobalt (Co), tungsten (W), or other appropriate materials. In some embodiments, the metal lines, the conductive features 280 include a barrier layer and a bulk metal layer over the barrier layer.

The present disclosure contemplates MLI structure 272 having more or less interconnect layers and/or levels, for example, a total number of N interconnect layers (levels) of with N as an integer ranging from 1 to 10.

In some embodiments, the passivation structure 276 is formed over the MLI structure 272. The passivation structure 276 may serve to protect devices in the substrate 268 and/or the MLI structure 272, for example, from exposure to contaminant particles, moisture, oxygen, etc. In some embodiments, the passivation structure 276 includes a passivation layer 286. The passivation layer 286 may be formed over the MLI structure 272 using a suitable process such as a process including a deposition process (such as a CVD process) and a chemical mechanical polishing (CMP) process. In an embodiment, the passivation layer 286 includes a dielectric material, such as silicon oxide, silicon nitride, silicon oxynitride (SiON), silicon carbon nitride (SiCN), silicon oxycarbide (SiOC), silicon carbide (SiC), silicon oxycarbonitride (SiOCN), epoxy, polyimide (PI), benzocyclobutene (BCB), polybenzoxazole (PBO), tetraethylorthosilicate (TEOS) oxide, or a combination thereof, and may include one layer of a dielectric material or multiple layers of dielectric materials. In some embodiments, the passivation layer 286 includes tetraethylorthosilicate (TEOS) oxide.

In some embodiments, the passivation structure 276 includes a plurality of contact pads 288 embedded in the passivation layer 286 and electrically connected to the conductive features 280 in the MLI structure 272. In some embodiments, the contact pads 288 each include a pad portion and via portion(s). The contact pads 288 may include aluminum, tungsten, some other metal or conductive material, or a combination thereof. In some embodiments, the contact pads 288 include aluminum. The passivation layer 286 may include a portion above a top surface of the contact pads 288. The portion may have a height H6 of about 1 μm to about 5 μm.

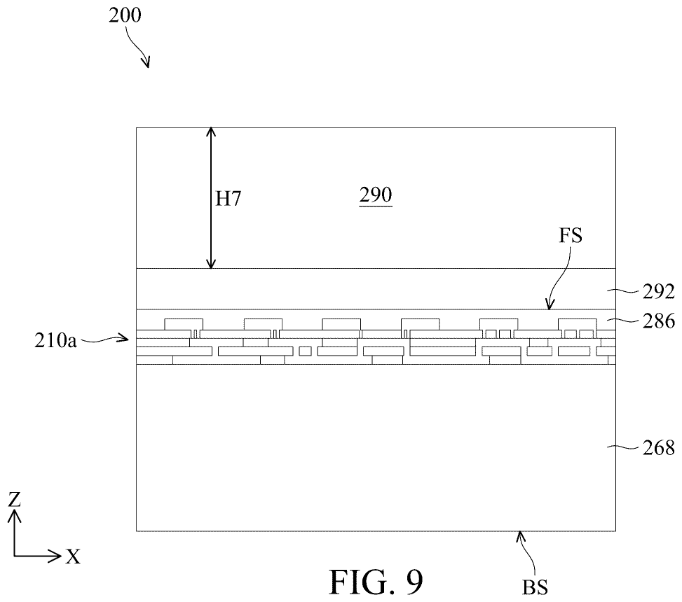

Referring to FIGS. 7 and 9, method 300 includes a block 314 where a first carrier piece 290 is bonded to the front surface FS of the die 210a to provide mechanical strength while the substrate 268 is thinned and partially removed later. The bonding of the first carrier piece 290 allows the die 210a to be flipped over for further processing and the first carrier piece 290 provides mechanical strength to the die 210a. To achieve that, a bonding layer 292 is deposited on the passivation layer 286 to interface the first carrier piece 290 in a direct bonding process. In some embodiments, the first carrier piece 290 includes elementary semiconductor, such as silicon (Si) or germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. In one embodiment, the first carrier piece 290 includes silicon (Si). In some alternative embodiments, the first carrier piece 290 includes glass. In some instances, the first carrier piece 290 has a thickness H7 of about 750 μm to about 800 μm.

In some embodiments, the bonding layer 292 is an oxide layer, such as a silicon oxide layer (e.g., an SiO₂ layer). In some embodiments, the bonding layer 292 is another suitable material that facilitates bonding of the first carrier piece 290 with the frontside of the die 210a.

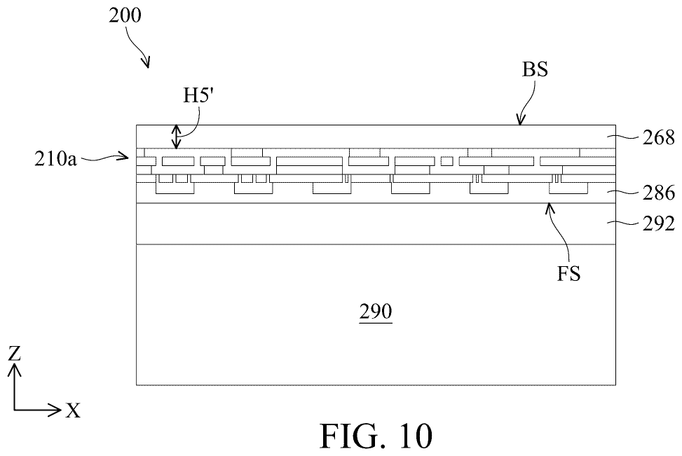

Referring to FIGS. 7 and 10, method 300 includes a block 316 where the substrate 268 of the die 210a is thinned. In some embodiments, the die 210a and the first carrier piece 290 are flipped over as depicted. The thinning of the substrate 268 is from the back surface BS of the die 210a. The thinning may include a mechanical grinding process and a chemical mechanical polishing (CMP). A substantial amount of substrate material may be first removed from the substrate 268 during a mechanical grinding process. Afterwards, a CMP process is performed to further thin down the substrate 268 and provide a planar back surface BS. The mechanical grinding process may reduce the height of the substrate 268 to about 25 μm to about 35 μm. The CMP process may further reduce the height of the substrate 268 to H5′ of about 15 μm to about 25 μm.

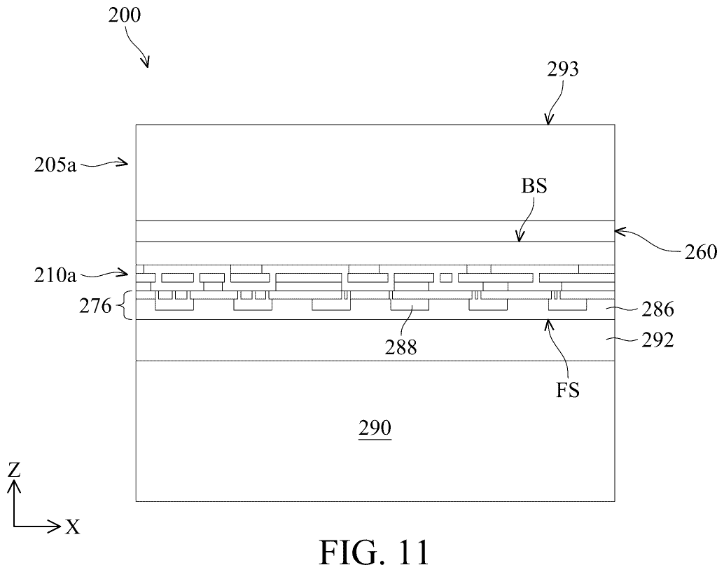

Referring to FIGS. 7 and 11, method 300 includes a block 318 where an IMC precursor 205a is bonded to the die 210a (e.g., by the bonding layer 260). The bonding may include any suitable method, such as deposition, applying heat (e.g., an annealing process), applying pressure, sintering, diffusion, or a combination thereof. In some embodiments, a TIM material (e.g., the first TIM, the second TIM as described above) is conformally deposited over the back surface BS of the die 210a. The IMC precursor 205a is disposed over the TIM material. In some embodiments, operations of block 318 further includes applying heat and/or pressure for a certain period (e.g., about 1 minute to about 30 minutes) to the TIM material between the IMC precursor 205a and the die 210a, thereby bonding the IMC precursor 205a and the die 210a. The TIM material may be heated at a temperature of about 300 F to about 600 F. The pressure may be applied to the TIM material along the Z-direction and be about 15 MPa to about 30 MPa. After applying heat and/or pressure, a thickness of the TIM material may be reduced (e.g., by greater than 50%) to the thickness of the bonding layer 260 as described above.

Still referring to FIGS. 7 and 11, method 300 includes a block 320 where a thickness of the IMC precursor 205a is reduced. Reducing the thickness (also referred to thinning) may include a mechanical grinding process and a CMP. A substantial amount of SCD may be first removed from the IMC precursor 205a during a mechanical grinding process. Afterwards, a CMP process is performed to further thin down the IMC precursor 205a and provide a planar surface 293. The thinning process may reduce the height of the IMC precursor 205a from an initial height (e.g., about 750 μm to about 800 μm) to H1 as described above.

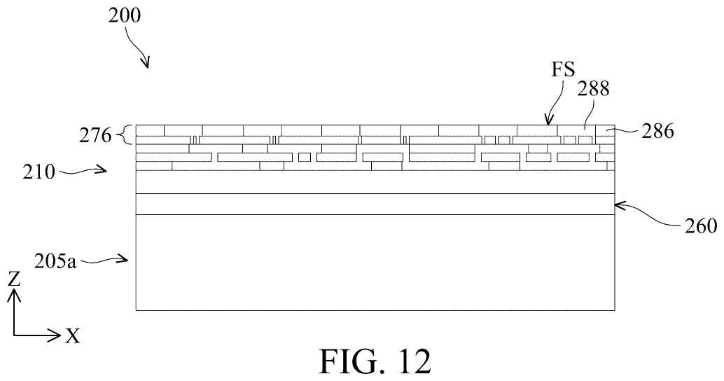

Referring to FIGS. 7 and 12, method 300 includes a block 322 where the first carrier piece 290, the bonding layer 292, and a portion of the passivation structure 276 are removed. After operations of bock 322, the die 210a forms the die 210 as described above. Operations of block 322 removes a portion of the passivation layers 286 above top surfaces of the contact pads 288, thus, the top surfaces of the contact pads 288 may be exposed thereafter. Operations of block 322 may include any suitable process, such as a mechanical grinding process and a CMP. In an example, a substantial amount of materials of the first carrier piece 290 may be first removed during a mechanical grinding process. Afterwards, a CMP process is performed to completely remove the first carrier piece 290 and the bonding layer 292, and to remove the portion of the passivation structure 276 to provide a planar front surface FS.

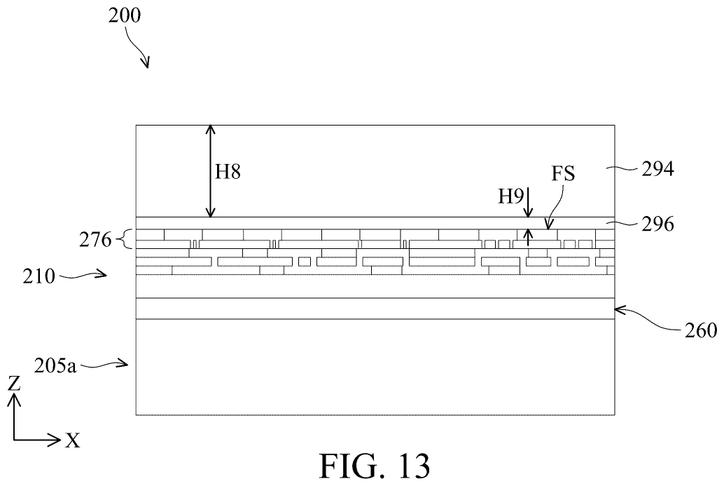

Referring to FIGS. 7 and 13, method 300 includes a block 324 where a second carrier piece 294 is bonded to the die 210 to provide mechanical strength while the IMC precursor 205a is etched later. The second carrier piece 294 may be bonded to the front surface FS of the die 210 by a glue layer 296. The bonding of the second carrier piece 294 allows the workpiece 200 to be flipped over for further processing and the second carrier piece 294 provides mechanical strength to the workpiece 200. To achieve that, a glue layer 296 is deposited on the passivation structure 276 to interface the second carrier piece 294 in a direct bonding process. The second carrier piece 294 may include similar materials as the first carrier piece 290 as described above. In some embodiments, the second carrier piece 294 includes glass. In some instances, the second carrier piece 294 has a thickness H8 of about 450 μm and about 550 μm.

In some embodiments, the glue layer 296 is an oxide layer, such as a silicon oxide layer (e.g., an SiO₂ layer). In some embodiments, the glue layer 296 is another suitable material that facilitates bonding of the second carrier piece 294 with the front surface FS of the die 210. The glue layer 296 may have a thickness H9 of about 50 μm to about 80 μm.

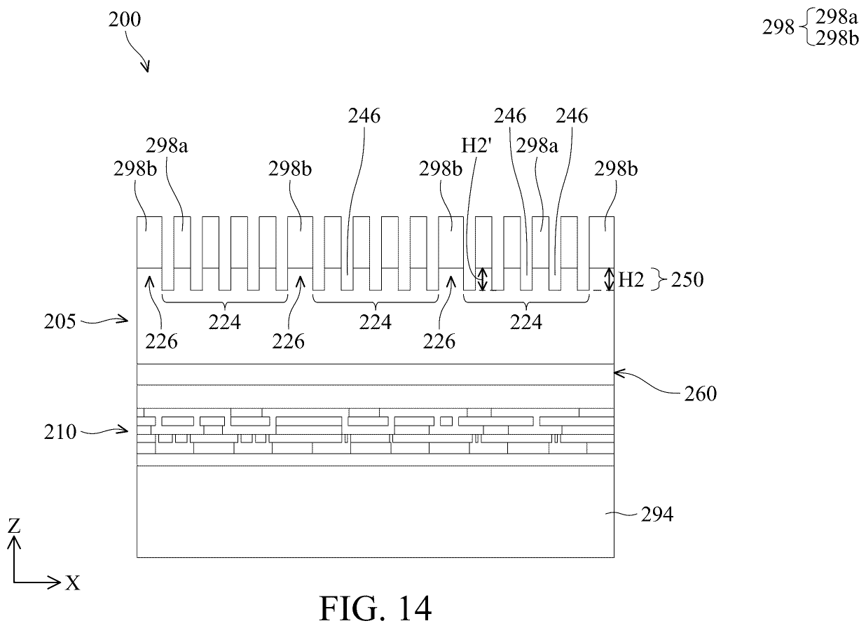

Referring to FIGS. 7 and 14, method 300 includes a block 326 where the IMC precursor 205a is patterned, thereby forming the IMC 205 as described above. Before patterning, the workpiece 200 may be flipped over as depicted in FIG. 14.

Forming the trenches 246 may include forming a hard mask layer 298 above the IMC precursor 205a and performing a lithography patterning and etching process to pattern the hard mask layer 298. The hard mask layer 298 may include SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, SiO₂, metals (e.g., Al, nickle), or other suitable materials. In some embodiments, the hard mask layer 298 includes Al or nickle. The patterning of the hard mask layer 298 forms openings directly above designed trench regions of the IMC precursor 205a.

In some alternative embodiments, instead of the lithography patterning, the hard mask layer 298 may be patterned using a pre-made mode having designed shapes. In some alternative embodiments, the hard mask layer 298 is pre-made and is used as a mask in the following etching processes to form the trenches 246.

Then, one or more etching processes are performed using the hard mask layer 298 as a mask to form the trenches 246. The one or more etching processes may include multiple steps and involve various etching fluids. The one or more etching processes may include any suitable methods, such as dry etching, wet etching, reactive ion etching (RIE), inductively coupled plasma (ICP) etching, and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, a hydrogen-containing gas, other suitable gases and/or plasmas, and/or combinations thereof. The etching process may use one or more etchant. A wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchants.

In some embodiments, under the same etching conditions (e.g., etchant, power, etc.) of the dry etching process, a ratio of a first etching rate of the IMC precursor 205a to a second etching rate of a silicon substrate (not depicted) may be equal to or less than about 1:10. In some embodiments, the ratio is about 1:10 to about 1:50. In some embodiments, the one or more etching processes takes about 30 minutes to about 24 hours.

In some embodiments, a first portion 298a of the hard mask layer 298 directly above the regions 224 is removed and a second portion 298b of the hard mask layer 298 directly above the partition walls 226 remains. This may use any suitable method such as patterning the hard mask layer 298. Additional etching processes, such as described above about the one or more etching processes may then be applied to the regions 224 of the IMC precursor 205a. Then the second portion 298b of the hard mask layer 298 is removed. In such embodiments, the height H2′ may be smaller than the height H2, resulting from the additional etching processes. In some other embodiments, after the one or more etching processes, the first portion 298a and the second portion 298b of the hard mask layer 298 are removed from the IMC precursor 205a. In such embodiments, the height H2′ is about equal to the height H2 as described above.

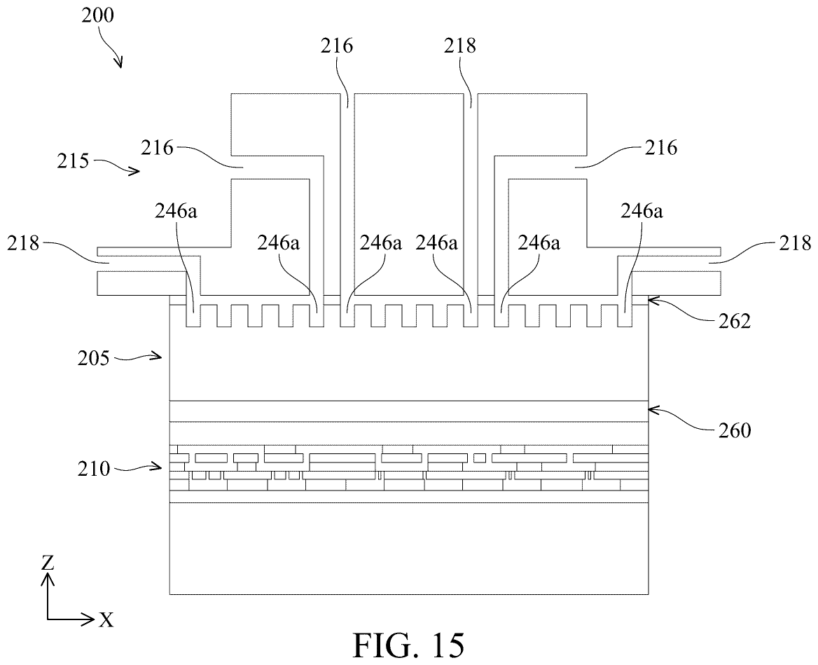

Referring to FIGS. 7 and 15, method 300 includes a block 328 where the cooling cover 215 is provided and bonded to the IMC 205. The workpiece 200 becomes the cooling unit 200 after operations of block 328. The sealing layer 262 may be deposited to top surfaces of the partition walls 226, and the cooling cover 215 may be placed over and bonded to the sealing layer 262 using any suitable method, such as a direct bonding process.

The cooling cover 215 is designed to include the inlet conduits 216 and the outlet conduits 218 as described above. Bonding the cooling cover 215 to the IMC 205 results in that the inlet conduits 216 and the outlet conduits 218 have openings to corresponding side trenches 246a therebelow.

Referring to FIG. 7, method 300 includes a block 330 where further processes, such as connecting the cooling unit 200 to the other components (e.g., the branch conduits 138 and 150) in the cooling system 100 may be performed.

Although not intended to be limiting, one or more embodiments of the present disclosure provide many benefits to a cooling system and the making thereof. For example, the present disclosure improves dissipation of the heat generated by a die by integrating the die with an IMC and a cooling cover disclosed herein. The IMC may be bonded to the die by a bonding layer disclosed herein, which may further improve the heat dissipation. With improved heat dissipation, heat accumulation in the die and thermal damage may be reduced and/or avoided and power consumption of the pump of the cooling system may be reduced.

In one exemplary aspect, the present disclosure is directed to a method of making a cooling unit. The method includes providing a workpiece including a device substrate and a passivation structure disposed over the device substrate, bonding a first carrier piece to the passivation structure, bonding an integrated micro cooler (IMC) precursor to the device substrate by a bonding layer, removing the first carrier piece, bonding a second carrier piece to the passivation structure, etching the IMC precursor to form a plurality of trenches and a partition wall surrounding the plurality of trenches, thereby forming an IMC, and bonding a cooling cover to the IMC. The IMC precursor includes single crystal diamond (SCD). The cooling cover includes a fluid inlet port and a fluid outlet port connected to the plurality of trenches by fluid conduits.

In some embodiments, the bonding layer has a thermal resistance of equal to or less than about 0.05 mm²·C/W. In some embodiments, the removing of the first carrier piece further removes a portion of the passivation structure. In some embodiments, the cooling cover includes SCD, copper, or a combination thereof, and the fluid conduits each include a T-shaped portion. In some embodiments, the bonding of the cooling cover to the IMC uses a sealant including a polymer-based material, a silicone-based material, or a combination thereof. In some embodiments, from a top view, the plurality of trenches are connected to have a zig-zag shape. In some embodiments, the plurality of trenches is a first plurality of trenches, the partition wall is a first partition wall, the fluid inlet port is a first fluid inlet port, and the fluid outlet port is a first fluid outlet port, the etching of the IMC precursor further forms a second plurality of trenches and a second partition wall dividing the second plurality of trenches from the first plurality of trenches, the second plurality of trenches and the second partition wall are surrounded by the first partition wall, and the cooling cover further includes a second fluid inlet port and a second fluid outlet port connected to the second plurality of trenches by the fluid conduits.

In another exemplary aspect, the present disclosure is directed to a method of making a cooling unit. The method includes providing a die having a first surface and a second surface opposite to the first surface, bonding the second surface of the die to a third surface of an integrated micro cooler (IMC) precursor by a bonding layer, etching from a fourth surface of the IMC precursor to form a plurality of trenches, thereby converting the IMC precursor to an IMC, and bonding a cooling cover to the fourth surface of the IMC. The IMC precursor includes single crystal diamond (SCD). The fourth surface of the IMC precursor is opposite to the third surface of the IMC precursor. The cooling cover includes a fluid inlet conduit and a fluid outlet conduit disposed over and open to the plurality of trenches.

In some embodiments, the cooling cover includes SCD, copper, or a combination thereof. In some embodiments, the bonding of the cooling cover to the fourth surface of the IMC is by a sealing layer, and the sealing layer includes a polymer-based material, a silicone-based material, or a combination thereof. In some embodiments, a thermal resistance of the bonding layer is equal to or less than about 0.05 mm²·C/W, and a thermal resistance of the sealing layer is equal to or greater than about 1 mm²·C/W. In some embodiments, the method further includes, before the etching from the fourth surface of the IMC precursor, reducing a thickness of the IMC precursor, and the IMC has a thickness of about 300 μm to about 750 μm. In some embodiments, the etching from the fourth surface of the IMC precursor includes depositing a hard mask layer over the IMC precursor, patterning the hard mask layer to form a patterned hard mask, and etching the fourth surface of the IMC precursor using the patterned hard mask as an etch mask. In some embodiments, the etching from the fourth surface of the IMC precursor further forms a partition wall surrounding the plurality of trenches, and the cooling cover is bonded to the partition wall. In some embodiments, from a top view, the IMC includes a plurality of zones, the plurality of trenches is a first plurality of trenches, the fluid inlet conduit is a first fluid inlet conduit, the fluid outlet conduit is a first fluid outlet conduit, the first plurality of trenches is in a first zone of the plurality of zones, the etching from the fourth surface of the IMC precursor further forms a second plurality of trenches in a second zone of the plurality of zones and separated from the first plurality of trenches by the partition wall, and the cooling cover further includes a second fluid inlet conduit and a second fluid outlet conduit open to the second plurality of trenches.

In yet another exemplary aspect, the present disclosure is directed to a system. The system includes a die, a bonding layer disposed over the die, an integrated micro cooler (IMC) disposed over the bonding layer, and a cooling cover disposed over the IMC. The IMC includes a first portion on the bonding layer and a second portion above the first portion, the second portion includes a plurality of trenches and a partition wall surrounding the plurality of trenches, the IMC includes a material of single crystal diamond (SCD), and the cooling cover includes a fluid inlet conduit and a fluid outlet conduit through the cooling cover and disposed over and open to the plurality of trenches.

In some embodiments, the system further includes a fluid path between the fluid inlet conduit and the fluid outlet conduit and outside the cooling cover, and a heat exchanger on the fluid path, the heat exchanger is configured to cool a coolant in the fluid path. In some embodiments, the system further includes a sealant bonding the IMC and the cooling cover, the sealant includes a polymer-based material, a silicone-based material, or a combination thereof. In some embodiments, the bonding layer has a thermal resistance of equal to or less than about 0.05 mm²·C/W. In some embodiments, the cooling cover includes SCD, copper, or a combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of making a cooling unit, comprising:
providing a workpiece including:
a device substrate and a passivation structure disposed over the device substrate;
bonding a first carrier piece to the passivation structure;
bonding an integrated micro cooler (IMC) precursor to the device substrate by a bonding layer, wherein the IMC precursor includes single crystal diamond (SCD);
removing the first carrier piece;
bonding a second carrier piece to the passivation structure;
etching the IMC precursor to form a plurality of trenches and a partition wall surrounding the plurality of trenches, thereby forming an IMC; and
bonding a cooling cover to the IMC, wherein the cooling cover includes a fluid inlet port and a fluid outlet port connected to the plurality of trenches by fluid conduits.

2. The method of claim 1, wherein the bonding layer has a thermal resistance of equal to or less than about 0.05 mm²·C/W.

3. The method of claim 1, wherein the removing of the first carrier piece further removes a portion of the passivation structure.

4. The method of claim 1,
wherein the cooling cover includes SCD, copper, or a combination thereof, and
wherein the fluid conduits each include a T-shaped portion.

5. The method of claim 1, wherein the bonding of the cooling cover to the IMC uses a sealant including a polymer-based material, a silicone-based material, or a combination thereof.

6. The method of claim 1, wherein from a top view, the plurality of trenches are connected to have a zig-zag shape.

7. The method of claim 1, wherein the plurality of trenches is a first plurality of trenches, the partition wall is a first partition wall, the fluid inlet port is a first fluid inlet port, and the fluid outlet port is a first fluid outlet port,
wherein the etching of the IMC precursor further forms a second plurality of trenches and a second partition wall dividing the second plurality of trenches from the first plurality of trenches,
wherein the second plurality of trenches and the second partition wall are surrounded by the first partition wall, and
wherein the cooling cover further includes a second fluid inlet port and a second fluid outlet port connected to the second plurality of trenches by the fluid conduits.

8. A method of making a cooling unit, comprising:
providing a die having a first surface and a second surface opposite to the first surface;
bonding the second surface of the die to a third surface of an integrated micro cooler (IMC) precursor by a bonding layer, wherein the IMC precursor includes single crystal diamond (SCD);
etching from a fourth surface of the IMC precursor to form a plurality of trenches, thereby converting the IMC precursor to an IMC, wherein the fourth surface of the IMC precursor is opposite to the third surface of the IMC precursor; and
bonding a cooling cover to the fourth surface of the IMC, wherein the cooling cover includes a fluid inlet conduit and a fluid outlet conduit disposed over and open to the plurality of trenches.

9. The method of claim 8, wherein the cooling cover includes SCD, copper, or a combination thereof.

10. The method of claim 8, wherein the bonding of the cooling cover to the fourth surface of the IMC is by a sealing layer, and
wherein the sealing layer includes a polymer-based material, a silicone-based material, or a combination thereof.

11. The method of claim 10,
wherein a thermal resistance of the bonding layer is equal to or less than about 0.05 mm²·C/W, and
wherein a thermal resistance of the sealing layer is equal to or greater than about 1 mm²·C/W.

12. The method of claim 8, further comprising, before the etching from the fourth surface of the IMC precursor, reducing a thickness of the IMC precursor, and
wherein the IMC has a thickness of about 300 μm to about 750 μm.

13. The method of claim 8, wherein the etching from the fourth surface of the IMC precursor includes:
depositing a hard mask layer over the IMC precursor;
patterning the hard mask layer to form a patterned hard mask; and
etching the fourth surface of the IMC precursor using the patterned hard mask as an etch mask.

14. The method of claim 8, wherein the etching from the fourth surface of the IMC precursor further forms a partition wall surrounding the plurality of trenches, and
wherein the cooling cover is bonded to the partition wall.

15. The method of claim 14, wherein from a top view, the IMC includes a plurality of zones,
wherein the plurality of trenches is a first plurality of trenches, the fluid inlet conduit is a first fluid inlet conduit, the fluid outlet conduit is a first fluid outlet conduit,
wherein the first plurality of trenches is in a first zone of the plurality of zones,
wherein the etching from the fourth surface of the IMC precursor further forms a second plurality of trenches in a second zone of the plurality of zones and separated from the first plurality of trenches by the partition wall, and
wherein the cooling cover further includes a second fluid inlet conduit and a second fluid outlet conduit open to the second plurality of trenches.

16. A system, comprising:
a die;
a bonding layer disposed over the die;
an integrated micro cooler (IMC) disposed over the bonding layer; and
a cooling cover disposed over the IMC,
wherein the IMC includes a first portion on the bonding layer and a second portion above the first portion,
wherein the second portion includes a plurality of trenches and a partition wall surrounding the plurality of trenches,
wherein the IMC includes a material of single crystal diamond (SCD), and
wherein the cooling cover includes a fluid inlet conduit and a fluid outlet conduit through the cooling cover and disposed over and open to the plurality of trenches.

17. The system of claim 16, further comprising:
a fluid path between the fluid inlet conduit and the fluid outlet conduit and outside the cooling cover, and
a heat exchanger on the fluid path, wherein the heat exchanger is configured to cool a coolant in the fluid path.

18. The system of claim 16, further comprising a sealant bonding the IMC and the cooling cover, wherein the sealant includes a polymer-based material, a silicone-based material, or a combination thereof.

19. The system of claim 16, wherein the bonding layer has a thermal resistance of equal to or less than about 0.05 mm²·C/W.

20. The system of claim 16, wherein the cooling cover includes SCD, copper, or a combination thereof.
